(19) United States
(12) Patent Application Publication
(10) Pub. No.: US 2018/0030587 A1
(43) Pub. Date: Feb. 1, 2018

(54) Heating Assembly

(71) Applicant: ROPEX Industrie-Elektronik GmbH, Bietigheim-Bissingen (DE)

(72) Inventors: Robert Peters, Bietigheim-Bissignen (DE); Alexander Hupp, Sulzfeld (DE); Maximilian Paul Baier, Stuttgart (DE)

(21) Appl. No.: 15/659,207

(22) Filed: Jul. 25, 2017

(30) Foreign Application Priority Data
Aug. 1, 2016 (EP) 16182214.3

(51) Int. Cl. C23C 14/06; C09D 7/14; C09D 7/12; C04B 35/01; C04B 35/515

(52) U.S. Cl. CPC C23C 14/06; C04B 35/01; C04B 35/515; C09D 7/1275; C09D 7/14

(57) ABSTRACT

A heating assembly for a thermal joining device, the heating assembly including a base body, through which a fluid passage passes and which is provided on an external surface with a heating device having a ceramic substrate designed as a thick-film ceramic material and a metallic heating conductor, wherein the heating conductor is produced from an anti-adhesion alloy, and/or wherein the heating conductor is coated with an anti-adhesion alloy coating, the anti-adhesion alloy containing a proportion of at least 5 percent by weight of at least one element from the group of the metals of the rare earths.

### BACKGROUND OF THE INVENTION

The invention relates to a heating assembly for a thermal joining device, the assembly comprising a base body through which a fluid passage passes and which is provided on an external surface with a heating device comprising a ceramic substrate designed as a thick-film ceramic material and a metallic heating conductor.

From DE 197 37 471 C2, a heating assembly for equipment for the thermal processing of films is known, which comprises a metallic substrate assigned to a cooling device, wherein an electrically insulating layer to which is applied at least one thick-film conductor track to act as heating conductor is applied to the substrate.

### SUMMARY OF THE INVENTION

The invention is based on the problem of providing a heating assembly which offers an improved service life if used for a thermal joining method.

For a heating assembly of the type referred to above, this problem is solved by the following features: heating assembly for a thermal joining device, the heating assembly comprising a base body through which a fluid passage passes and which is provided on an external surface with a heating device comprising a ceramic substrate designed as a thick-film ceramic material and a metallic heating conductor, wherein the heating conductor is produced from an anti-adhesion alloy, and/or that the heating conductor is coated with an anti-adhesion alloy coating, the anti-adhesion alloy containing a proportion of at least 5 percent by weight of an element from the group of the metals of the rare earths.

A period of use or a service life of a heating assembly of the type referred to above, which is in particular used in welding plastic film, essentially depends on the action of an anti-adhesion coating. This anti-adhesion coating is applied to the metallic heating conductor in order to prevent an adhesion of the material to be welded to the heating conductor during the joining process. Known anti-adhesion coatings for heating conductors are usually based on polymer compounds, in particular on the use of polytetrafluoroethylene compounds (PTFE). With such anti-adhesion coatings, an adhesion of the material to be welded to the heating conductor can initially be reliably avoided in a heating assembly in mint condition. However, the anti-adhesion coating is worn by mechanical loading, in particular abrasion, so that the anti-adhesion properties deteriorate in the longer term.

In contrast, if the heating conductor is produced from an anti-adhesion alloy and/or coated with an anti-adhesion alloy which includes a proportion of at least one element from the group of the metals of the rare earths (cerium, dysprosium, erbium, europium, gadolinium, holmium, lanthanum, lutetium, neodymium, praseodymium, promethium, samarium, scandium, terbium, thulium, ytterbium, yttrium), a thermally stable and abrasion-resistant anti-adhesion coating can be created with which a service life of the heating assembly can be improved considerably.

Basic chemical compositions for such anti-adhesion coatings are disclosed in WO 2013/141877 A1, which is herewith expressly made the subject matter of this disclosure. The material compositions and material properties disclosed in WO 2013/141877 A1 are advantageously used for the heating assembly referred to above. The interaction of the anti-adhesion alloy with the ceramic substrate and/or the metallic heating conductor results in synergistic effects, in particular in terms of improving a thermal conduction between the metallic heating conductor and the materials to be welded and in terms of isolating the heating conductor and/or the substrate from thermally soluble and potentially corrosive components of the material to be welded. In addition, the use of anti-adhesion alloys containing metals of the rare earths improves the wear resistance of the anti-adhesion coating and thus the service life of the heating assembly.

It is preferably provided that at least the one element used of the metals of the rare earths is used in the form of an oxide, a nitride or carbide. This applies in particular if the anti-adhesion alloy is to be electrically insulating. If the anti-adhesion alloy is intended to be electrically conductive, at least the metallic elements of the metals of the rare earths can be used in their pure form or as alloys with further materials, in particular metals.

It can optionally be provided that the ceramic substrate is present as a not yet hardened green body when the anti-adhesion alloy is applied, so that the ceramic substrate and the anti-adhesion alloy are fired together, or that the ceramic substrate is hardened before the anti-adhesion alloy is applied.

Advantageous further developments of the invention are the subject matter of the dependent claims.

It is expedient if the heating conductor is applied to the ceramic substrate as an amorphous mass, in particular in a spraying or screen printing process or in a direct printing process, and joined to the substrate by adhesive force, in particular involving thermal effects. For producing the heating conductor, an amorphous mass is used, this being in particular an initially viscous or thin solution of metallic particles and particles of at least one element from the group of the metals of the rare earths in a suitable binder. In this way, a freely selectable, in particular complex, geometry for the heating conductor can be produced by simple means. This applies in particular to the use of a screen printing method, in which the amorphous mass is pressed through free openings of an otherwise closed screen, so that complex geometries can be created for the heating conductor in a single operation. When using a direct printing method, it is provided that the amorphous mass is applied to the ceramic substrate in a freely selectable manner through a discharge nozzle located on a push-button which can be moved in at least one, preferably in two and in particular in three, linear spatial directions. When using a spraying method, it is preferably provided that the amorphous mass is applied locally to the ceramic substrate in order to form one or more closed tracks for the electric heating conductor. In all of the above procedures, it is provided that, following the application to the ceramic substrate, a thermal action is used to harden the amorphous mass and to join it to the ceramic substrate by adhesive force. This thermal action may, for example, be a firing process in a suitable kiln, in particular at temperatures above 700° C. In this context, it can optionally be provided that the ceramic substrate is present as a not yet hardened green body, so that the ceramic substrate and the heating conductor are fired together, or that the ceramic substrate is hardened before the heating conductor is applied.

In an alternative further development of the invention, it is provided that the heating conductor is produced from a strip material which is in particular joined to the substrate by adhesive force. This strip material can optionally be represented by an anti-adhesion alloy containing a proportion of at least 5 percent by weight of at least one element from the group of the metals of the rare earths or by one of the metallic materials commonly used for the production of heating conductors, in particular a stainless steel alloy. It can further be provided that the at least widely dimensionally stable, possibly flexible strip material is placed on the ceramic substrate for producing the heating conductor and joined thereto by adhesive force in a suitable production step in order to ensure a durable connection between the heating conductor and the substrate.

In an advantageous further development of the invention, it is provided that an intermediate layer is placed between the substrate and the heating conductor for the improvement of an adhesive joint between the substrate and the heating conductor. The intermediate layer is preferably electrically insulating, being in particular a layer of a ceramic compound with proportions of at least one oxide or carbide or nitride or fluoride or boride or silicate of a metal of the rare earths. The use of an intermediate layer is of particular interest if the heating conductor is likewise made of an anti-adhesion alloy present as strip material or as a hardened, initially amorphous, mass, because in this way the adhesive joint with the ceramic substrate can be improved.

It is preferably provided that an intermediate layer is placed between the heating conductor and an anti-adhesion alloy coating applied to the heating conductor for the improvement of an adhesive joint between the heating conductor and the anti-adhesion alloy, the intermediate layer being preferably electrically insulating, being in particular a layer of a ceramic compound with proportions of at least one oxide or carbide or nitride or fluoride or boride or silicate of a metal of the rare earths. Such an intermediate layer can be of interest both for a heating conductor without a proportion of metals of the rare earths and for a heating conductor containing at least 5 percent by weight of at least one element from the group of the metals of the rare earths. In either case, the intermediate layer provides a particularly reliable bond between the anti-adhesion alloy coating to be applied to the heating conductor and the heating conductor, thereby offering a particularly advantageous service life for the heating assembly.

In a further development of the invention, it is provided that the anti-adhesion alloy coating applied to the heating conductor is designed as an electric insulation layer. In this way, the anti-adhesion alloy coating has a dual function, because, in addition to preventing an adhesion between the heating conductor and the materials to be welded, it ensures that the heating conductor is electrically insulated against the environment.

It is expedient if an anti-adhesion alloy coating applied to the heating conductor is produced by spraying or sputtering or printing or dipping. These methods can ensure a cost-effective and precise application of the anti-adhesion alloy coating to the heating conductor. By means of the sputtering (cathode atomising) method, particularly thin layers of the anti-adhesion alloy coating can be applied to the heating conductor. By means of the other methods, in particular printing or dipping, thicker layers of the anti-adhesion alloy coating can be applied to the heating conductor. By means of a spraying method, a layer thickness range above sputtering but below printing or dipping can be covered.

In a further development of the invention, it is provided that the heating conductor is produced from a first anti-adhesion alloy having a first part by weight of at least one element from the group of the metals of the rare earths and that the heating conductor is coated with a coating of a second anti-adhesion alloy having a second part by weight of at least one element from the group of the metals of the rare earths, the first part by weight being less than the second part by weight. With such a design of the heating conductor and the anti-adhesion alloy coating applied thereto, an advantageous connection between the heating conductor and the substrate and an advantageous connection between the heating conductor and the applied anti-adhesion alloy coating can be ensured. In this, concentration gradients between the substrate, the hearing conductor and the anti-adhesion alloy coating are reduced in terms of the respective part by weight of metals of the rare earths, so that large jumps between the respective part by weight for the elements from the group of the metals of the rare earths are avoided, resulting in stable adhesive joints between the respective layers.

It is preferably provided that a first layer thickness of a coating applied to the heating conductor is less than 500 micrometers, preferably less than 100 micrometers, particularly preferably less than 40 micrometers and in particular less than 20 micrometers. This in particular ensures an advantageous thermal coupling between the heating conductor and the materials to be welded together, because a reliable ant-adhesion action of the anti-adhesion alloy coating can be ensured even with very low layer thicknesses.

### BRIEF DESCRIPTION OF THE DRAWINGS

Advantageous embodiments of the invention are illustrated in the drawing, of which:

FIG. 1 shows a first embodiment of a heating assembly on which a coating of an anti-adhesion alloy is formed,

FIG. 2 shows a second embodiment of a heating assembly in which the heating conductor and a coating applied thereto are formed from an anti-adhesion alloy,

FIG. 3 shows a further embodiment of a heating assembly in which the heating conductor and the coating are formed from an anti-adhesion alloy and an intermediate layer is formed between the heating conductor and the substrate,

FIG. 4 shows a further embodiment of a heating assembly in which a coating of a heating conductor is produced from an anti-adhesion alloy and the heating conductor is applied to an intermediate layer opposite the substrate,

FIG. 5 shows a further embodiment of a heating assembly in which a coating on the heating conductor is produced from an anti-adhesion alloy and the heating conductor is applied to an intermediate layer opposite the ceramic substrate,

FIG. 6 shows a further embodiment of a heating assembly in which the heating conductor and a coating applied to the heating conductor are produced from an anti-adhesion alloy and an intermediate layer each is formed between the heating conductor and the applied coating and the ceramic substrate, and

FIG. 7 is a side view of a heating assembly.

### DETAILED DESCRIPTION

In the following description of the various embodiments of the invention, reference numbers varying by the amount of twenty are used for components of identical function.

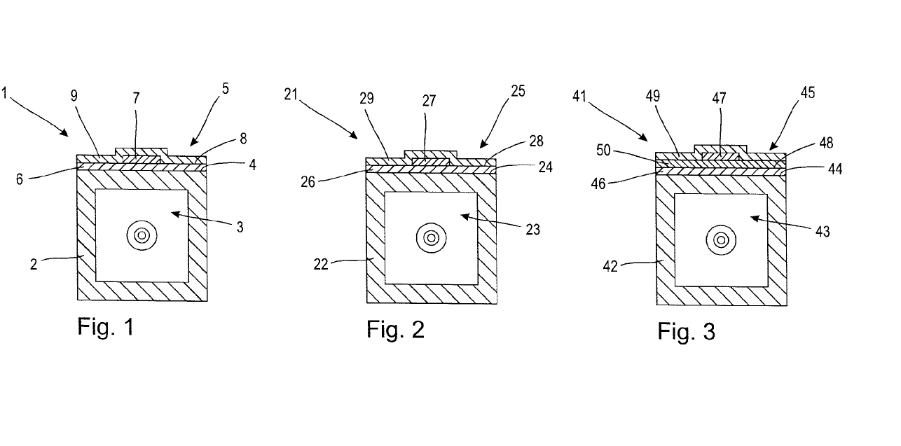

A first embodiment of a heating assembly 1 shown in FIG. 1 is provided for use in a joining machine not shown in the drawing, in particular in a welding machine for plastic film. The heating assembly 1 comprises a profiled base body 2, which is designed as a rectangular tube purely by way of example. In its interior, the base body 2 has a fluid passage 3, through which a coolant, preferably a cooling liquid, in particular water, can flow if the heating assembly 1 is used in a joining machine not shown in the drawing. By way of example, it is provided that the base body 2 is made of a metallic material, in particular aluminium or stainless steel, and that the ceramic substrate 6 is applied to the outer surface 4 of the base body 2 using a thick film method. The substrate 6 is in particular used for the electric insulation and the thermal coupling of the heating conductor 7 located on a substrate surface 8 of the ceramic substrate 6 against the base body 2.

Purely by way of example, it is provided that the heating conductor 7 has a rectangular cross-section extending in a strip shape along the base body 2. In the embodiment according to FIG. 1, the heating conductor 7 is produced from an amorphous mass with a proportion of metal, in particular silver, which is joined to the ceramic substrate 6 by adhesive force in a suitable manner. In order to avoid an adhesion of a workpiece not shown in the drawing, in particular a plastic film, to the heating conductor 7, which comes into direct contact with the workpiece during a joining operation, a coating 9 is provided, which covers both the heating conductor 7 and the rest of the substrate surface 8 not covered by the heating conductor 7, and which is designed as an anti-adhesion alloy.

The coating designed as an anti-adhesion alloy preferably comprises a proportion of at least 5 percent by weight of at least one element from the group of the metals of the rare earths and is in particular represented by an oxide or carbide or nitride or fluoride or boride or silicate. The coating 9, which, like the heating conductor 7 and the ceramic substrate 6, is not shown true to scale, can be applied by spraying, sputtering, screen printing or dipping, for example.

In the illustrated embodiment, it is provided that the ceramic substrate has a layer thickness in the range of less than 0.1 millimetres, the heating conductor has a thickness of less than 0.07 millimetres and the coating 9 has a thickness of less than 0.04 millimetres.

The second embodiment of a heating assembly 21 shown in FIG. 2 differs from the heating assembly 1 according to FIG. 1 in that the heating conductor 27 is produced from an anti-adhesion alloy with a proportion of at least 5 percent by weight of at least one element from the group of the metals of the rare earths. The heating conductor 27 can optionally be applied to the associated ceramic substrate 26 as an amorphous mass or joined to the ceramic substrate 26 in the form of a strip material by adhesive force.

In the third embodiment of a heating assembly 41 shown in FIG. 3, both the heating conductor 47 and the coating 49 are formed from an anti-adhesion alloy like in the second embodiment of the heating assembly 21 shown in FIG. 2. In addition, an intermediate layer 50 is provided between the ceramic substrate 46 and the heating conductor 47, the intermediate layer 50 being preferably electrically insulating and in particular a layer of a ceramic compound with proportions of at least one oxide or carbide or nitride or fluoride or boride or silicate of a metal of the rare earths. The intermediate layer 50 is likewise not shown true to scale and provides an advantageous adhesive coupling between the heating conductor 47 and the ceramic substrate 46.

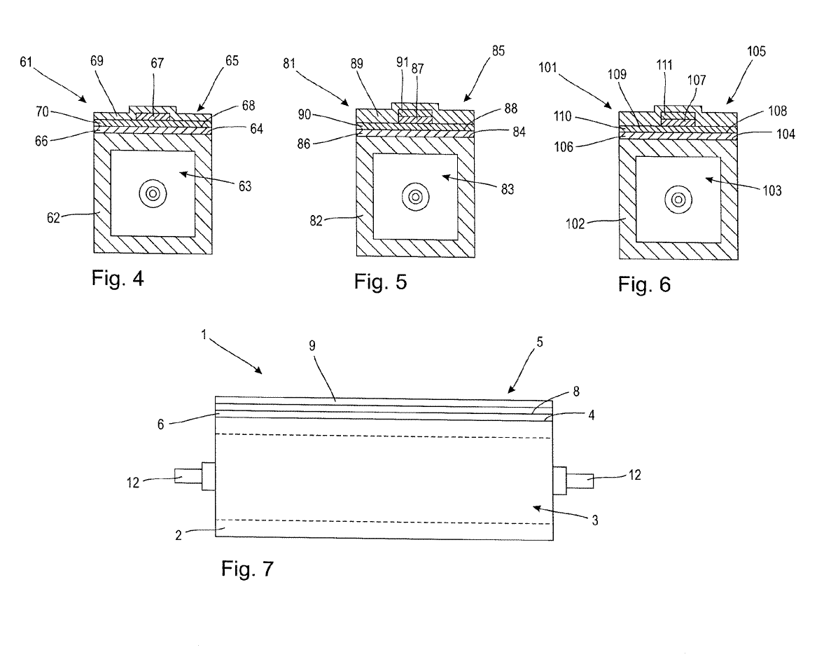

The fourth embodiment of a heating assembly 61 shown in FIG. 4 differs from the heating assembly according to FIG. 3 in that the heating conductor 67 is produced from a metallic material commonly used for such heating conductors, for example from a stainless steel alloy. In this embodiment, there is likewise provided an intermediate layer 70 between the heating conductor 67 and the ceramic substrate 66, and the anti-adhesion alloy coating 69 is joined to the intermediate layer 70 by adhesive force in some areas.

The fifth embodiment of a heating assembly 81 shown in FIG. 5 is a variant of the first embodiment of a heating assembly 1 as shown in FIG. 1, wherein an intermediate layer 90 is provided between the heating conductor 87 made of a metallic material, for example stainless steel, and the ceramic substrate 86. This intermediate layer 90 can in particular be represented by an electrically insulating alloy, in the illustrated embodiment by a layer of a ceramic compound with proportions of at least one oxide or carbide or nitride or fluoride or boride or silicate of a metal of the rare earths. The intermediate layer 90 is used to improve the adhesive joint between the heating conductor 87, which is produced from a conventional material such as copper or silver with a proportion of glass, in particular from an amorphous mass, and the coating 89, which is produced from an anti-adhesion alloy. This applies in the same way to the intermediate layer 91 between the heating conductor 87 and the coating 89 represented by an anti-adhesion alloy.

The sixth embodiment of a heating assembly 101 shown in FIG. 6 is a variant of the third embodiment of a heating assembly 41 as shown in FIG. 3, in which, in addition to the intermediate layer 110 between the heating conductor 107 and the ceramic substrate 106, a further intermediate layer 111 is provided between the heating conductor 107 and the coating 109 represented by an anti-adhesion alloy.

FIG. 7 is, purely by way of example, a side view of the heating assembly 1 according to FIG. 1. End connectors 12 for supplying and discharging a coolant to and from the fluid passage 3, which is indicated by broken lines only, are fitted to the base body 2, which is designed as a rectangular tube in the illustrated embodiment.

What is claimed is:

1. A heating assembly for a thermal joining device, the assembly comprising a base body, through which a fluid passage passes and which is provided on an external surface with a heating device comprising a ceramic substrate designed as a thick-film ceramic material and a metallic heating conductor, wherein the heating conductor is produced from an anti-adhesion alloy, and/or wherein the heating conductor is coated with an anti-adhesion alloy coating, the anti-adhesion alloy containing a proportion of at least 5 percent by weight of at least one element from the group of the metals of the rare earths.

2. The heating assembly according to claim 1, wherein the heating conductor is applied to the ceramic substrate as an amorphous mass, and joined to the substrate by adhesive force.

3. The heating assembly according to claim 2, wherein the heating conductor is applied to the ceramic substrate in a spraying or screen printing process or in a direct printing process.

4. The heating assembly according to claim 2, wherein the heating conductor is joined to the substrate involving thermal effects,

5. The heating assembly according to claim 1, wherein the heating conductor is produced from a strip material.

6. The heating assembly according to claim 1, wherein an intermediate layer is placed between the substrate and the heating conductor for the improvement of an adhesive joint between the substrate and the heating conductor.

7. The heating assembly according to claim 6, wherein the intermediate layer is electrically insulating.

8. The heating assembly according to claim 6, wherein the intermediate layer is a layer of a ceramic compound with proportions of at least one oxide or carbide or nitride or fluoride or boride or silicate of a metal of the rare earths.

9. The heating assembly according to claim 1, wherein an intermediate layer is placed between the heating conductor and an anti-adhesion alloy coating for the improvement of an adhesive joint between the heating conductor and the anti-adhesion alloy.

10. The heating assembly according to claim 9, wherein the intermediate layer is electrically insulating.

11. The heating assembly according to claim 9, wherein the intermediate layer is a layer of a ceramic compound with proportions of at least one oxide or carbide or nitride or fluoride or boride or silicate of a metal of the rare earths.

12. The heating assembly according to claim 1, wherein the coating applied to the heating conductor is formed as an electrically insulating layer from an anti-adhesion alloy.

13. The heating assembly according to claim 1, wherein the anti-adhesion alloy coating applied to the heating conductor is produced by spraying or sputtering or printing or dipping.

14. The heating assembly according to claim 1, wherein the heating conductor is produced from a first anti-adhesion alloy having a first part by weight of at least one element from the group of the metals of the rare earths, and wherein the heating conductor is coated with a coating of a second anti-adhesion alloy having a second part by weight of at least one element from the group of the metals of the rare earths, the first part by weight being less than the second part by weight.

15. The heating assembly according to claim 1, wherein a layer thickness of an anti-adhesion alloy coating applied to the heating conductor is less than 500 micrometers.

16. The heating assembly according to claim 15, wherein the layer thickness of the anti-adhesion alloy coating is less than 100 micrometers.

17. The heating assembly according to claim 15, wherein the layer thickness of the anti-adhesion alloy coating is less than 40 micrometers.

18. The heating assembly according to claim 15, wherein the layer thickness of the anti-adhesion alloy coating is less than 20 micrometers.
